(19) United States
(12) Patent Application Publication
(10) Pub. No.: US 2026/0094636 A1
(43) Pub. Date: Apr. 2, 2026

(54) CONTROL SIGNAL TO SUPPORT CLOCK SYNC FEATURE AT SELF-REFRESH EXIT

(71) Applicant: Micron Technology, Inc., Boise, ID (US)

(72) Inventor: Jaeil Kim, Suwanee, GA (US)

(21) Appl. No.: 19/297,942

(22) Filed: Aug. 12, 2025

Related U.S. Application Data
(60) Provisional application No. 63/700,449, filed on Sep. 27, 2024.

(51) Int. Cl. G11C 11/406; G11C 11/4076

(52) U.S. Cl. CPC G11C 11/40615; G11C 11/40603; G11C 11/4076

(57) ABSTRACT

Methods, systems, and devices for synchronizing clock signals at an exit of a self-refresh mode are described. A memory device may implement techniques to avoid errors caused by the swapping of the at least two clock signals. For example, the memory device may be configured to delay the swapping of the at least two clock signals, which may enable the memory device to swap the at least two clock signals (e.g., from an even clock signal to an odd clock signal, and vice-versa) during a duration where commands are not to be issued to the memory device. In some examples, a control signal may be used to trigger the lockout signal and the swapping of the at least two clock signals. As such, the memory device may avoid errors due to timing inconsistencies associated with exiting the self-refresh mode, such as during chip select operations.

### CROSS REFERENCE

The present application for patent claims priority to U.S. Patent Application No. 63/700,449 by Kim, entitled “CONTROL SIGNAL TO SUPPORT CLOCK SYNC FEATURE AT SELF-REFRESH EXIT,” filed Sep. 27, 2024, which is assigned to the assignee hereof, and which is expressly incorporated by reference in its entirety herein.

### TECHNICAL FIELD

The following relates to one or more systems for memory, including synchronizing clock signals at an exit of a self-refresh mode.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports synchronizing clock signals at an exit of a self-refresh mode in accordance with examples as disclosed herein.

FIG. 2 shows an example of a circuitry that supports synchronizing clock signals at an exit of a self-refresh mode in accordance with examples as disclosed herein.

FIG. 3 shows an example of a timing diagram that supports synchronizing clock signals at an exit of a self-refresh mode in accordance with examples as disclosed herein.

FIG. 4 shows a block diagram of a memory system that supports synchronizing clock signals at an exit of a self-refresh mode in accordance with examples as disclosed herein.

FIG. 5 shows a flowchart illustrating a method or methods that support synchronizing clock signals at an exit of a self-refresh mode in accordance with examples as disclosed herein.

### DETAILED DESCRIPTION

Some memory devices may be configured to perform refresh operations during a self-refresh mode. In some cases, a memory device may adjust duty cycle timings during the self-refresh mode. When exiting the self-refresh mode, in some examples, at least two clock signals (e.g., a first and second internal clock signals) may be swapped, which may cause a misalignment between the clock signals (at least temporarily). For example, the misalignment between the clock signals may cause errors (e.g., violations) associated with one or more clock switch capture circuits of the memory device. As such, the memory device may be configured to activate a lockout signal during which the memory device may swap the at least two clock signals (e.g., during a self-refresh exit procedure). In some cases, however, as a pulse width of the lockout signal may be determined by an asynchronous delay, errors (e.g., timing margin fails) may still occur during the transition to enable or disable the lockout signal.

In accordance with examples as described herein, the memory device may implement techniques to avoid errors caused by the swapping of the at least two clock signals. For example, the memory device may be configured to delay the swapping of the at least two clock signals, which may enable the memory device to swap the at least two clock signals (e.g., from an even clock signal to an odd clock signal, and vice-versa) during a duration where commands are not to be issued to the memory device. In some examples, a control signal may be used to trigger the lockout signal and the swapping of the at least two clock signals. As such, the memory device may avoid errors due to timing inconsistencies associated with exiting the self-refresh mode.

In addition to applicability in memory systems as described herein, techniques for synchronizing clock signals at an exit of a self-refresh mode may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory timings and reducing timing errors, which may decrease processing or latency times, decrease error incidence, or otherwise improve user experience, among other benefits.

Features of the disclosure are illustrated and described in the context of systems and architectures. Features of the disclosure are further illustrated and described in the context of circuitry, timing diagrams, and flowcharts.

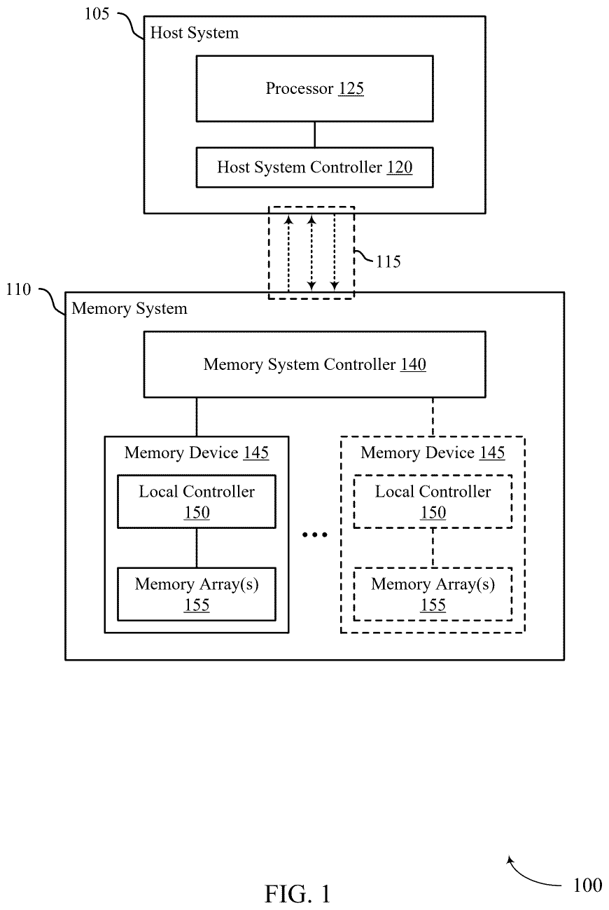

FIG. 1 illustrates an example of a system 100 that supports synchronizing clock signals at an exit of a self-refresh mode in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

In some examples, the memory system 110 and memory devices 145 may support self-refresh operations. In some examples, during self-refresh, memory devices 145 may autonomously manage refresh cycles, which may reduce power consumption during periods of inactivity or low power states. For example, instead of relying on external commands to maintain data integrity, the memory devices 145 may internally generate refresh signals to perform refresh operations for one or more memory cells. This may allow other system components (e.g., the memory system controller 140) to enter deeper sleep states, thereby extending battery life of devices. In some examples, the transition into and out of self-refresh mode may be controlled by specific commands.

In accordance with examples as described herein, memory devices 145 may implement techniques to avoid errors caused by the swapping of the at least two clock signals during an exit of a self-refresh mode. For example, a memory device 145 may be configured synchronize at least two clock signals (e.g., internal clock signals) during an exit of a self-refresh procedure). The memory device 145 may delay the swapping of the at least two clock signals, which may enable the memory device to swap the at least two clock signals (e.g., from an even clock signal to an odd clock signal, and vice-versa) during a duration where commands are not to be issued to the memory device by the memory system controller 140. In some examples, a control signal may be used to trigger the lockout signal and the swapping of the at least two clock signals. As such, the memory device 145 may avoid errors due to timing inconsistencies associated with exiting the self-refresh mode and may avoid errors for commands issued from the memory system controller 140.

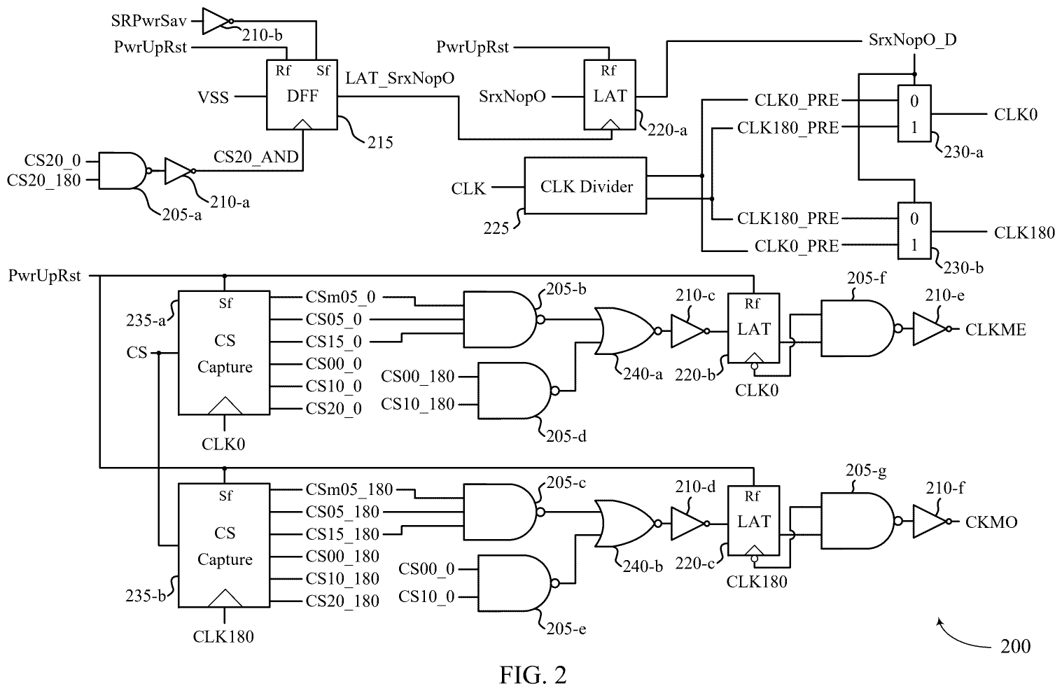

FIG. 2 shows an example of a circuitry 200 that supports synchronizing clock signals at an exit of a self-refresh mode in accordance with examples as disclosed herein. In some examples, the circuitry may be implemented within a memory device 145, as described herein, or otherwise within one or more components of a memory system 110.

In some examples, the circuitry may include a NAND gate 205-a, which may use a first and second chip select signals (e.g., CS20_0 and CS20_180) as inputs. The output of the NAND gate 205-a may be coupled with an inverter 210-a. In some examples, the first and second chip select signals may be in-phase with a respective clock signal, such as an even clock signal (e.g., for CS20_0) and an odd clock signal (e.g., for CS20_180). The output of the NAND gate 205-a may be an input for an inverter 210-a, which may result in a signal (e.g., CS20_AND) corresponding to an AND operation performed on the first and second chip select signals.

The signal outputted by the inverter 210-a may be used as a clock signal for a data flip flop (DFF) 215. The DFF 215 may use a voltage input (e.g., a ground or zero voltage, VSS) as an input (e.g., as a data input), and may use a power reset signal (e.g., PwrUpRst) as a reset signal for resetting the DFF 215, and a set signal that is associated with initiating a power saving mode for self-refresh operations (e.g., SRPwrSav). The DFF 215 may output a latch signal (e.g., LAT_SrxNopO) associated with a timing of self-refresh exit and no-operation procedures (e.g., when no commands are to be issued to the memory device 145), which may be input into a latch 220-a.

The latch 220-a may use the latch signal as a clock signal input, and may also be configured to use a signal associated with the indication of self-refresh exit (e.g., SrxNopO) as an input (e.g., as a data input), which may be associated with a duration when no commands are to be issued to the memory device 145. The latch 220-a may also use the power reset signal (e.g., PwrUpRst) as a reset signal for resetting the latch 220-a. The latch 220-a may output a delayed signal (e.g., SrxNopO_D) corresponding to the signal indicating the self-refresh exit. As such, the delayed signal may be used to delay a swapping of internal clock signals at the memory device 145 and avoid timing conflicts, as described herein.

For example, the circuitry 200 may include a clock divider 225 (e.g., CLK divider) which may receive a clock signal (e.g., CLK, an external clock signal) and divide the clock signal into an even clock signal (e.g., CLK0_PRE) and an odd clock signal (e.g., CLK180_PRE). Each of the even clock signal and the odd clock signal may be used as inputs for a multiplexer 230-a and a multiplexer 230-b, and the delayed signal may be used as a control signal for each of the multiplexer 230-a and the multiplexer 230-b. When the delayed clock signal is asserted (e.g., transitioned) to a first value (e.g., 0), the multiplexer 230-a may select the even signal, while the multiplexer 230-b may select the odd signal. Similarly, when the delayed clock signal is asserted to a second value (e.g., 1), the multiplexer 230-a may select the odd signal, while the multiplexer 230-b may select the even signal.

Accordingly, the output of the multiplexer 230-a may generate a first internal clock signal (e.g., CLK0) and the output of the multiplexer 230-b may generate a second internal clock signal (e.g., CLK180) for the memory device 145. Additionally, as each of the multiplexer 230-a and the multiplexer 230-b use the delayed signal (e.g., SrxNopO_D) as a control signal, a swapping of the clock signals may be performed with a delay from the assertion (e.g., change in value) of the signal associated with the self-refresh exit (e.g., SrxNopO). The swapping may refer to the change of the first internal clock signal (e.g., CLK0) from being based on the even signal (e.g., CLK0_PRE) to being based on the odd signal (e.g., CLK180_PRE), while the second internal clock signal (e.g., CLK180) is changed from being based on the odd signal (e.g., CLK180_PRE) to being based on the even signal (e.g., CLK0_PRE), or vice-versa, using the multiplexer 230-a and the multiplexer 230-b and based on the delayed signal. As such, the swapping of the clock signals and assertion of a lockout signal (e.g., prior to the swapping) may occur during a duration when no operations are to be received by the memory device 145, which may thereby avoid timing errors caused by the swapping or the assertion of the lockout signal.

The first internal clock signal and the second internal clock signal may be used as inputs for a chip select capture circuit 235-a and a chip select capture circuit 235-b, respectively. Each of the chip select capture circuit 235-a and the chip select capture circuit 235-b may each use a chip select signal (e.g., CS) as inputs (e.g., as data inputs), and may use the power reset signal (e.g., PwrUpRst) as a set signal. The chip select capture circuit 235-a may output a set of even chip select signals (e.g., CSm05_0, CS05_0, CS15_0, CS00_0, CS10_0, and CS20_0) based on the first internal clock signal and the chip select signal. Similarly, the chip select capture circuit 235-b may output a set of odd chip select signals (e.g., CSm05_180, CS05_180, CS15_180, CS00_180, CS10_180, and CS20_180) based on the second internal clock signal and the chip select signal.

A first subset of the set of even chip select signals (e.g., CSm05_0, CS05_0, and CS15_0) may be input into a NAND gate 205-b, while a first subset of the odd chip select signals (e.g., CS00_180 and CS10_180) may be input into a NAND gate 205-d. The outputs of the NAND gate 205-b and the NAND gate 205-d may be input into a NOR gate 240-a, and the corresponding output may be input into an inverter 210-c. The output of the inverter 210-c may be input into a latch 220-b, which may use the power reset signal as a reset signal for the latch 220-b, and may use the first internal clock signal (e.g., CLK0) as a clock signal. The output of the latch 220-b and the first internal clock signal may be input into a NAND gate 205-f and the corresponding output may be input into an inverter 210-e, resulting in an AND operation performed on the output of the latch 220-b and the first internal clock signal. This resulting signal (e.g., CLKME) may be used as an even clock signal for one or more components (e.g., even master latches) of the memory device 145 during one or more access operations.

Similarly, a second subset of the set of odd chip select signals (e.g., CSm05_180, CS05_180, and CS15_180) may be input into a NAND gate 205-c, and a second subset of the set of even chip select signals (e.g., CS00_0 and CS10_0) may be input into a NAND gate 205-c. The outputs of the NAND gate 205-b and the NAND gate 205-d may be input into a NOR gate 240-b, and the corresponding output may be input into an inverter 210-d. The output of the inverter 210-d may be input into a latch 220-c, which may use the power reset signal as a reset signal for the latch 220-c, and may use the second internal clock (e.g., CLK180) signal as a clock signal. The output of the latch 220-c and the second internal clock signal may be input into a NAND gate 205-g and the corresponding output may be input into an inverter 210-f, resulting in an AND operation performed on the output of the latch 220-c and the second internal clock signal. This resulting signal (e.g., CLKMO) may be used as an odd clock signal for one or more components (e.g., odd master latches) of the memory device 145 during access operations.

As such, by avoiding timing inconsistencies due to the delayed swapping of the first internal clock signal and the second internal clock signal, timing errors may be avoided while performing chip select procedures, thereby reducing errors occurring due to the exit of the self-refresh mode.

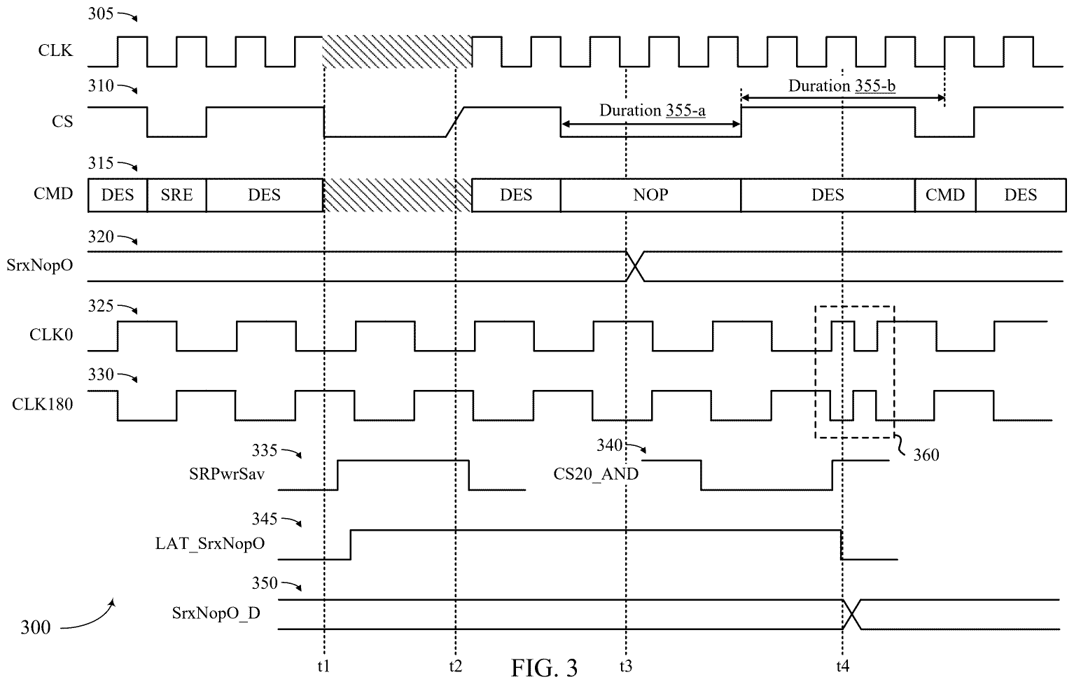

FIG. 3 shows an example of a timing diagram 300 that supports synchronizing clock signals at an exit of a self-refresh mode in accordance with examples as disclosed herein. The timing diagram 300 illustrates values of signals associated with a memory device 145 while entering and exiting a self-refresh mode. The signaling and timing described may avoid timing errors caused by a lockout signal and swapping of internal clock signals, as described herein.

The timing diagram 300 illustrates a values over time for a clock signal 305, a chip select signal 310, one or more no-operation signals 320 (e.g., SrxNopO), an internal clock signal 325 (e.g., CLK0), an internal clock signal 330 (e.g., CLK 180), a self-refresh power saving signal 335 (e.g., SrPwrSav), a signal 340 (e.g., CS20_AND) corresponding to an AND operation performed on a first and second chip select signals, a latch signal 345 associated with an exit from the self-refresh mode, and one or more delayed signals 350 corresponding to the one or more no-operation signals 320. Additionally, the timing diagram 300 may illustrate a command line 315, which may illustrate issued commands and corresponding durations. In some cases, durations illustrated by the timing diagram 300 may not be to scale, or may include other operations or durations not shown.

The clock signal 305 may be an example of a clock signal received from an external source (e.g., a host system), or an internal clock generated based on a clock signal received from the external source. The clock signal 305 may correspond to the CLK signal input into the clock divider 225 described with reference to FIG. 2.

The chip select signal 310 may correspond to the CS signal input into the chip select capture circuit 235-a and the chip select capture circuit 235-b described with reference to FIG. 2. The no-operation signals 320 may be examples of the signal associated with an indication of self-refresh exit (e.g., SrxNopO) which may be input into the latch 220-a, as described with reference to FIG. 2.

The internal clock signal 325 may be an example of the first internal clock signal output by the multiplexer 230-a and input into the latch 220-b, the chip select capture circuit 235-a, and the NAND gate 205-f, as described with reference to FIG. 2. Similarly, the internal clock signal 330 may be an example of the second internal clock signal output by the multiplexer 230-b and input into the latch 220-c, the chip select capture circuit 235-b, and the NAND gate 205-g as described with reference to FIG. 2.

The self-refresh power saving signal 335 may be an example of the set signal for the DFF 215 associated with initiating the power saving mode for self-refresh operations, as described with reference to FIG. 2. In some examples, the signal 340 may be an example of the signal corresponding to the AND operation performed on the first and second chip select signals output by the inverter 210-a, described with reference to FIG. 2.

The latch signal 345 may correspond to the latch signal (e.g., LAT_SrxNopO) associated with the timing of self-refresh exit and no-operation procedures input into the latch 220-a described with reference to FIG. 2. The one or more delayed signals 350 may be examples of the delayed signal (e.g., SrxNopO_D) used as a control signal for the multiplexer 230-b for delaying the swapping of the clock signals, as described with reference to FIG. 2.

In some examples, the command line 315 may show deselect (e.g., DES) commands, which may correspond to durations where the memory device 145 does not receive a command (e.g., a no-operation period) or receives a command indicating no operation to be performed. The command line 315 may illustrate a self-refresh enter command (e.g., SRE), which may trigger the memory device 145 to enter the self-refresh mode. This may cause the self-refresh power saving signal 335 to be asserted, after t1, to a first value (e.g., a high value), which may be associated with an indeterminate state for the clock signal 305 and the command line 315 (e.g., while the memory device 145 performs self-refresh operations). The latch signal 345 may be asserted to the first value based on the assertion of the self-refresh power saving signal 335. In some cases, the de-assertion of the self-refresh power saving signal 335 to a second value (e.g., a low value), after t2, may trigger a self-refresh exit procedure.

During the self-refresh exit procedure, the chip select signal 310 may, at (e.g., during, around) t2, ramp to the first value. Subsequently, at t3, the one or more no-operation signals 320 may swap values (e.g., from the first value to the second value and vice versa), which may indicate a no-operation period occurring during a duration 335-a (e.g., a (CSL_SRexit). The duration 335-a may correspond to a time during which the chip select signal 310 is low (e.g., at the second value) and no commands are to be issued to the memory device 145 (e.g., a no-operation period, where a memory system 110 or a memory system controller 140 may refrain from issuing commands to the memory device 145). The swapping of the one or more no-operation signals 320 may trigger the signal 340 to assert to the second value.

After the duration 355-a, the signal 340 may assert to the first value, which may trigger the latch signal 345 to assert, at t4, to the second value. The latch signal 345 asserting to the second value may trigger, at t4 (e.g., subsequent to t4), the one or more delayed signals 350 to swap, which may trigger, during a duration 360, the swapping of the internal clock signal 325 and the internal clock signal 330. As such, the swapping of the internal clock signal 325 and the internal clock signal 330 may occur during a duration 355-b (e.g., a tXS timing), which may correspond to an exit latency for the self-refresh procedure.

In some examples, a lockout signals may be activated at least over the duration 360. In some cases, the lockout signal may indicate, while activated (e.g., asserted to the first value), that no commands are to be issued to the memory device 145 (e.g., that the memory system 110 or the memory system controller 140 are to refrain from issuing commands to the memory device 145) or that no operations are to be performed using the internal clock signal 325 and the internal clock signal 330. As such, the lockout signal may be active while the swapping of the internal clock signal 325 and the internal clock signal 330 occur, thereby preventing timing errors from occurring due to the swapping. The lockout signal may be deactivated after the duration 360 (e.g., or during) after the swapping has been performed.

In some cases, the memory device 145 may determine a current state of the internal clock signal 325 and the internal clock signal 330 prior to the swapping (e.g., prior to the duration 360). For example, the memory device 145 may determine that the internal clock signal 325 and the internal clock signal 330 are desynchronized, and may determine to perform the swap based on the current state of the internal clock signal 325 and the internal clock signal 330. Alternatively, the memory device 145 may determine that the internal clock signal 325 and the internal clock signal 330 are synchronized (e.g., using correct timings, corresponding to one of an even clock signal or an odd clock signal), and may refrain from performing the swapping of the internal clock signal 325 and the internal clock signal 330.

Accordingly, the swapping of the internal clock signal 325 and the internal clock signal 330 may occur during a period where no operations responsive to commands are to be issued, and would not interfere or cause errors during other operations, such as chip select operations, of the memory device 145.

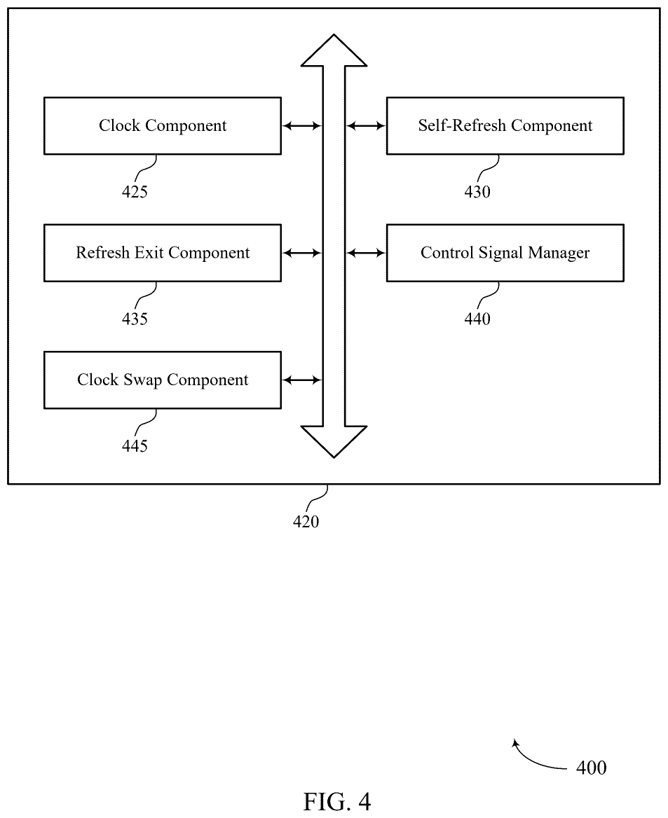

FIG. 4 shows a block diagram 400 of a memory system 420 that supports synchronizing clock signals at an exit of a self-refresh mode in accordance with examples as disclosed herein. The memory system 420 may be an example of aspects of a memory system as described with reference to FIGS. 1 through 3. The memory system 420, or various components thereof, may be an example of means for performing various aspects of synchronizing clock signals at an exit of a self-refresh mode as described herein. For example, the memory system 420 may include a clock component 425, a self-refresh component 430, a refresh exit component 435, a control signal manager 440, a clock swap component 445, or any combination thereof. Each of these components, or components of subcomponents thereof (e.g., one or more processors, one or more memories), may communicate, directly or indirectly, with one another (e.g., via one or more buses).

The clock component 425 may be configured as or otherwise support a means for generating an even clock signal and an odd clock signal based on a clock signal received by a memory device. The self-refresh component 430 may be configured as or otherwise support a means for performing one or more self-refresh operations using a first internal clock signal and a second internal clock signal as part of operating in a self-refresh mode, where the first internal clock signal is based on the even clock signal and the second internal clock signal is based on the odd clock signal. The refresh exit component 435 may be configured as or otherwise support a means for initiating an exit procedure for a self-refresh mode. The control signal manager 440 may be configured as or otherwise support a means for transitioning, as part of the exit procedure for the self-refresh mode, a value of a control signal from a first value to a second value in response to exiting the self-refresh mode. The clock swap component 445 may be configured as or otherwise support a means for swapping, as part of the exit procedure for the self-refresh mode and in response to transitioning the value of the control signal, the even clock signal and the odd clock signal such that first internal clock signal is based on the odd clock signal and the second internal clock signal is based on the even clock signal.

In some examples, the clock swap component 445 may be configured as or otherwise support a means for swapping the even clock signal and the odd signal during a duration associated with the exit procedure, where the memory system is configured to refrain from issuing commands to one or more memory devices during the duration.

In some examples, the control signal manager 440 may be configured as or otherwise support a means for activating a lockout signal, where the swapping of the even clock signal and the odd clock signal is performed while the lockout signal is active.

In some examples, the control signal manager 440 may be configured as or otherwise support a means for deactivating the lockout signal during the duration, where the swapping of the even clock signal and the odd clock signal occurs before the deactivation of the lockout signal.

In some examples, the self-refresh component 430 may be configured as or otherwise support a means for initiating the self-refresh mode. In some examples, the self-refresh component 430 may be configured as or otherwise support a means for enabling a power saving mode in response to initiating the self-refresh mode. In some examples, the control signal manager 440 may be configured as or otherwise support a means for transitioning the value of the control signal from the second value to the first value in response to enabling the power saving mode.

In some examples, the refresh exit component 435 may be configured as or otherwise support a means for disabling the power saving mode in response to initiating the exit procedure for the self-refresh mode, where transitioning the value of the control signal from the first value to the second value is in response to disabling the power saving mode.

In some examples, the control signal manager 440 may be configured as or otherwise support a means for transitioning, in response to transitioning the control signal to the first value, a latch signal associated with the exit procedure from a first value to a second value in response to disabling the power saving mode. In some examples, the control signal manager 440 may be configured as or otherwise support a means for transitioning the latch signal for self-refresh exit from the second value to the first value in response to a value of a chip select signal, where transitioning the value of the control signal is in response to transitioning the latch signal to the first value.

In some examples, the clock component 425 may be configured as or otherwise support a means for determining, after initiating the exit procedure, a current state of the first internal clock signal, the second internal clock signal, or both, where swapping the even clock signal and the odd clock signal is based on determining the current state of the first internal clock signal, the second internal clock signal, or both.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

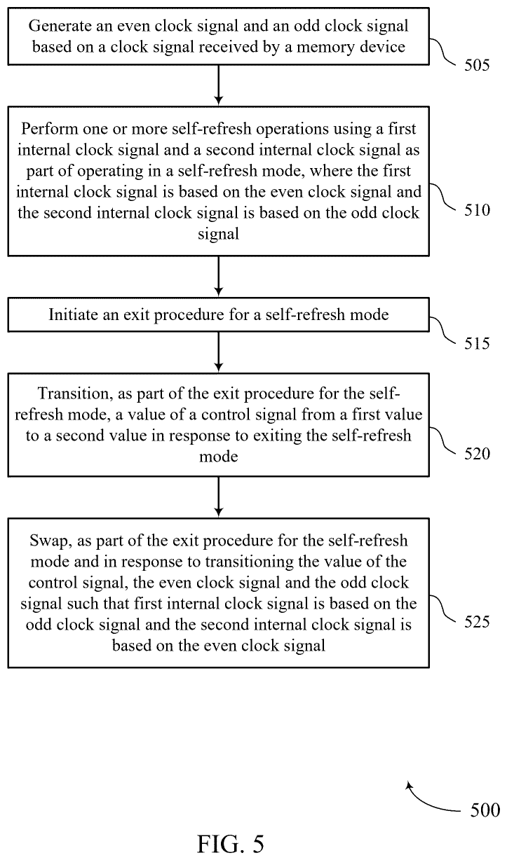

FIG. 5 shows a flowchart illustrating a method 500 that supports synchronizing clock signals at an exit of a self-refresh mode in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include generating an even clock signal and an odd clock signal based on a clock signal received by a memory device. In some examples, aspects of the operations of 505 may be performed by a clock component 425 as described with reference to FIG. 4.

At 510, the method may include performing one or more self-refresh operations using a first internal clock signal and a second internal clock signal as part of operating in a self-refresh mode, where the first internal clock signal is based on the even clock signal and the second internal clock signal is based on the odd clock signal. In some examples, aspects of the operations of 510 may be performed by a self-refresh component 430 as described with reference to FIG. 4.

At 515, the method may include initiating an exit procedure for a self-refresh mode. In some examples, aspects of the operations of 515 may be performed by a refresh exit component 435 as described with reference to FIG. 4.

At 520, the method may include transitioning, as part of the exit procedure for the self-refresh mode, a value of a control signal from a first value to a second value in response to exiting the self-refresh mode. In some examples, aspects of the operations of 520 may be performed by a control signal manager 440 as described with reference to FIG. 4.

At 525, the method may include swapping, as part of the exit procedure for the self-refresh mode and in response to transitioning the value of the control signal, the even clock signal and the odd clock signal such that first internal clock signal is based on the odd clock signal and the second internal clock signal is based on the even clock signal. In some examples, aspects of the operations of 525 may be performed by a clock swap component 445 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for generating an even clock signal and an odd clock signal based on a clock signal received by a memory device; performing one or more self-refresh operations using a first internal clock signal and a second internal clock signal as part of operating in a self-refresh mode, where the first internal clock signal is based on the even clock signal and the second internal clock signal is based on the odd clock signal; initiating an exit procedure for a self-refresh mode; transitioning, as part of the exit procedure for the self-refresh mode, a value of a control signal from a first value to a second value in response to exiting the self-refresh mode; and swapping, as part of the exit procedure for the self-refresh mode and in response to transitioning the value of the control signal, the even clock signal and the odd clock signal such that first internal clock signal is based on the odd clock signal and the second internal clock signal is based on the even clock signal.

Aspect 2: The method, apparatus, or non-transitory computer-readable medium of aspect 1, further including operations, features, circuitry, logic, means, or instructions, or any combination thereof for swapping the even clock signal and the odd signal during a duration associated with the exit procedure, where the memory system is configured to refrain from issuing commands to one or more memory devices during the duration.

Aspect 3: The method, apparatus, or non-transitory computer-readable medium of aspect 2, further including operations, features, circuitry, logic, means, or instructions, or any combination thereof for activating a lockout signal, where the swapping of the even clock signal and the odd clock signal is performed while the lockout signal is active.

Aspect 4: The method, apparatus, or non-transitory computer-readable medium of aspect 3, further including operations, features, circuitry, logic, means, or instructions, or any combination thereof for deactivating the lockout signal during the duration, where the swapping of the even clock signal and the odd clock signal occurs before the deactivation of the lockout signal.

Aspect 5: The method, apparatus, or non-transitory computer-readable medium of any of aspects 1 through 4, further including operations, features, circuitry, logic, means, or instructions, or any combination thereof for initiating the self-refresh mode; enabling a power saving mode in response to initiating the self-refresh mode; and transitioning the value of the control signal from the second value to the first value in response to enabling the power saving mode.

Aspect 6: The method, apparatus, or non-transitory computer-readable medium of aspect 5, further including operations, features, circuitry, logic, means, or instructions, or any combination thereof for disabling the power saving mode in response to initiating the exit procedure for the self-refresh mode, where transitioning the value of the control signal from the first value to the second value is in response to disabling the power saving mode.

Aspect 7: The method, apparatus, or non-transitory computer-readable medium of aspect 6, further including operations, features, circuitry, logic, means, or instructions, or any combination thereof for transitioning, in response to transitioning the control signal to the first value, a latch signal associated with the exit procedure from a first value to a second value in response to disabling the power saving mode and transitioning the latch signal for self-refresh exit from the second value to the first value in response to a value of a chip select signal, where transitioning the value of the control signal is in response to transitioning the latch signal to the first value.

Aspect 8: The method, apparatus, or non-transitory computer-readable medium of any of aspects 1 through 7, further including operations, features, circuitry, logic, means, or instructions, or any combination thereof for determining, after initiating the exit procedure, a current state of the first internal clock signal, the second internal clock signal, or both, where swapping the even clock signal and the odd clock signal is based on determining the current state of the first internal clock signal, the second internal clock signal, or both.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
generate an even clock signal and an odd clock signal based on a clock signal received by a memory device;
perform one or more self-refresh operations using a first internal clock signal and a second internal clock signal as part of operating in a self-refresh mode, wherein the first internal clock signal is based on the even clock signal and the second internal clock signal is based on the odd clock signal;
initiate an exit procedure for a self-refresh mode;
transition, as part of the exit procedure for the self-refresh mode, a value of a control signal from a first value to a second value in response to exiting the self-refresh mode; and
swap, as part of the exit procedure for the self-refresh mode and in response to transitioning the value of the control signal, the even clock signal and the odd clock signal such that first internal clock signal is based on the odd clock signal and the second internal clock signal is based on the even clock signal.

2. The memory system of claim 1, wherein the processing circuitry is further configured to cause the memory system to:
swap the even clock signal and the odd signal during a duration associated with the exit procedure, wherein the memory system is configured to refrain from issuing commands to one or more memory devices during the duration.

3. The memory system of claim 2, wherein the processing circuitry is further configured to cause the memory system to:
activate a lockout signal, wherein the swapping of the even clock signal and the odd clock signal is performed while the lockout signal is active.

4. The memory system of claim 3, wherein the processing circuitry is further configured to cause the memory system to:
deactivate the lockout signal during the duration, wherein the swapping of the even clock signal and the odd clock signal occurs before the deactivation of the lockout signal.

5. The memory system of claim 1, wherein the processing circuitry is further configured to cause the memory system to:
initiate the self-refresh mode;
enable a power saving mode in response to initiating the self-refresh mode; and
transition the value of the control signal from the second value to the first value in response to enabling the power saving mode.

6. The memory system of claim 5, wherein the processing circuitry is further configured to cause the memory system to:
disable the power saving mode in response to initiating the exit procedure for the self-refresh mode, wherein transitioning the value of the control signal from the first value to the second value is in response to disabling the power saving mode.

7. The memory system of claim 6, wherein the processing circuitry is further configured to cause the memory system to:
transition, in response to transitioning the control signal to the first value, a latch signal associated with the exit procedure from a first value to a second value in response to disabling the power saving mode; and
transition the latch signal for self-refresh exit from the second value to the first value in response to a value of a chip select signal, wherein transitioning the value of the control signal is in response to transitioning the latch signal to the first value.

8. The memory system of claim 1, wherein the processing circuitry is further configured to cause the memory system to:
determine, after initiating the exit procedure, a current state of the first internal clock signal, the second internal clock signal, or both, wherein swapping the even clock signal and the odd clock signal is based on determining the current state of the first internal clock signal, the second internal clock signal, or both.

9. A method by a memory system, comprising:
generating an even clock signal and an odd clock signal based on a clock signal received by a memory device;
performing one or more self-refresh operations using a first internal clock signal and a second internal clock signal as part of operating in a self-refresh mode, wherein the first internal clock signal is based on the even clock signal and the second internal clock signal is based on the odd clock signal;
initiating an exit procedure for a self-refresh mode;
transitioning, as part of the exit procedure for the self-refresh mode, a value of a control signal from a first value to a second value in response to exiting the self-refresh mode; and
swapping, as part of the exit procedure for the self-refresh mode and in response to transitioning the value of the control signal, the even clock signal and the odd clock signal such that first internal clock signal is based on the odd clock signal and the second internal clock signal is based on the even clock signal.

10. The method of claim 9, further comprising:
swapping the even clock signal and the odd signal during a duration associated with the exit procedure, wherein the memory system is configured to refrain from issuing commands to one or more memory devices during the duration.

11. The method of claim 10, further comprising:
activating a lockout signal, wherein the swapping of the even clock signal and the odd clock signal is performed while the lockout signal is active.

12. The method of claim 11, further comprising:
deactivating the lockout signal during the duration, wherein the swapping of the even clock signal and the odd clock signal occurs before the deactivation of the lockout signal.

13. The method of claim 9, further comprising:
initiating the self-refresh mode;
enabling a power saving mode in response to initiating the self-refresh mode; and
transitioning the value of the control signal from the second value to the first value in response to enabling the power saving mode.

14. The method of claim 13, further comprising:
disabling the power saving mode in response to initiating the exit procedure for the self-refresh mode, wherein transitioning the value of the control signal from the first value to the second value is in response to disabling the power saving mode.

15. The method of claim 14, further comprising:
transitioning, in response to transitioning the control signal to the first value, a latch signal associated with the exit procedure from a first value to a second value in response to disabling the power saving mode; and
transitioning the latch signal for self-refresh exit from the second value to the first value in response to a value of a chip select signal, wherein transitioning the value of the control signal is in response to transitioning the latch signal to the first value.

16. The method of claim 9, further comprising:
determining, after initiating the exit procedure, a current state of the first internal clock signal, the second internal clock signal, or both, wherein swapping the even clock signal and the odd clock signal is based on determining the current state of the first internal clock signal, the second internal clock signal, or both.

17. A non-transitory computer-readable medium storing code, the code comprising instructions executable by one or more processors to:
generate an even clock signal and an odd clock signal based on a clock signal received by a memory device;
perform one or more self-refresh operations using a first internal clock signal and a second internal clock signal as part of operating in a self-refresh mode, wherein the first internal clock signal is based on the even clock signal and the second internal clock signal is based on the odd clock signal;
initiate an exit procedure for a self-refresh mode;
transition, as part of the exit procedure for the self-refresh mode, a value of a control signal from a first value to a second value in response to exiting the self-refresh mode; and
swap, as part of the exit procedure for the self-refresh mode and in response to transitioning the value of the control signal, the even clock signal and the odd clock signal such that first internal clock signal is based on the odd clock signal and the second internal clock signal is based on the even clock signal.

18. The non-transitory computer-readable medium of claim 17, wherein the instructions are further executable by the one or more processors to:
swap the even clock signal and the odd signal during a duration associated with the exit procedure.

19. The non-transitory computer-readable medium of claim 18, wherein the instructions are further executable by the one or more processors to:
activate a lockout signal, wherein the swapping of the even clock signal and the odd clock signal is performed while the lockout signal is active.

20. The non-transitory computer-readable medium of claim 19, wherein the instructions are further executable by the one or more processors to:
deactivate the lockout signal during the duration, wherein the swapping of the even clock signal and the odd clock signal occurs before the deactivation of the lockout signal.

21. The non-transitory computer-readable medium of claim 17, wherein the instructions are further executable by the one or more processors to:
initiate the self-refresh mode;
enable a power saving mode in response to initiating the self-refresh mode; and
transition the value of the control signal from the second value to the first value in response to enabling the power saving mode.

22. The non-transitory computer-readable medium of claim 21, wherein the instructions are further executable by the one or more processors to:
disable the power saving mode in response to initiating the exit procedure for the self-refresh mode, wherein transitioning the value of the control signal from the first value to the second value is in response to disabling the power saving mode.
